(19) United States
(12) Patent Application Publication
(10) Pub. No.: US 2014/0159069 A1
(43) Pub. Date: Jun. 12, 2014

(54) LIGHT EMITTING DEVICE AND METHOD FOR MANUFACTURING THE SAME

(71) Applicant: ADVANCED OPTOELECTRONIC TECHNOLOGY, INC., HSINCHU HSIEN (TW)

(72) Inventors: MING-TA TSAI, Hukou (TW); CHIH-PENG HSU, Hukou (TW); CHUNG-MIN CHANG, Hukou (TW)

(73) Assignee: ADVANCED OPTOELECTRONIC TECHNOLOGY, INC., Hsinchu Hsien (TW)

(21) Appl. No.: 14/067,913

(22) Filed: Oct. 30, 2013

(30) Foreign Application Priority Data
Dec. 7, 2012 (CN) 2012105223079

(51) Int. Cl. H01L 33/56

(52) U.S. Cl. CPC H01L 33/56
USPC 257/88; 438/27

(57) ABSTRACT

A light emitting device includes a light source module and a secondary optical element. The optical element includes a light incident surface and a light radiating surface opposite to the light incident surface. The light source module includes at least one light emitting unit, and the light emitting unit includes a light emitting diode (LED) chip and an encapsulation layer. The encapsulation layer includes a light outputting surface. The light incident surface faces to the light outputting surface. A gap is defined between the light outputting surface and the light incident surface, and a transparent colloid is filled in the gap. The transparent colloid has a refractive index similar to that of the second optical element and the encapsulation layer. A method for manufacturing the light emitting device is also provided.

### BACKGROUND

1. Technical Field

The present disclosure generally relates to a light emitting device and a method for manufacturing the light emitting device, and particularly to a light emitting device having a high light outputting efficiency and a method for manufacturing the light emitting device.

2. Description of the Related Art

LEDs have low power consumption, high efficiency, quick reaction time, long lifetime, and the absence of toxic elements such as mercury during manufacturing. Due to these advantages, traditional light sources are gradually replaced by LEDs.

A typical light emitting device such as direct type backlight module includes an LED light source and a secondary optical element engaging with the LED light source. The secondary optical element includes a light incident surface and a light outputting surface opposite to the light incident surface, and the LED light source faces to the light incident surface. Conventionally, the LED light source are spaced from the secondary optical element to form a gap therebetween; light generated by the LED light source first radiates into the air in the gap and thereafter enters the secondary optical element via the light incident surface. However, due to a sudden enormous change of a refractive index in an interface between a light output surface the LED light source and the air in the gap, a part of light emitted by the conventional LED light source is easily reflected back and even totally reflected; accordingly, the part of light emitted by the LED light source is lost which leads to a low light output efficiency.

Therefore, it is desirable to provide a light emitting device and method for manufacturing the same which can overcome the above-described problems.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting device and method for manufacturing the same. Moreover, in the drawings, all the views are schematic, and like reference numerals designate corresponding parts throughout the views.

FIG. 1 is a cross-sectional view of a light emitting device in accordance with one embodiment of the present disclosure.

FIG. 2 is a schematic view showing an optical spectrum of the light emitting device of FIG. 1 and an optical spectrum of a conventional light emitting device.

FIG. 3 is a schematic view showing an optical spectrum of the light emitting device of FIG. 1 wherein an encapsulation layer thereof is changed to have multiple kinds of fluorescent particles and an optical spectrum of a conventional light emitting device wherein an encapsulation layer thereof has the same multiple kinds of fluorescent particles.

### DETAILED DESCRIPTION

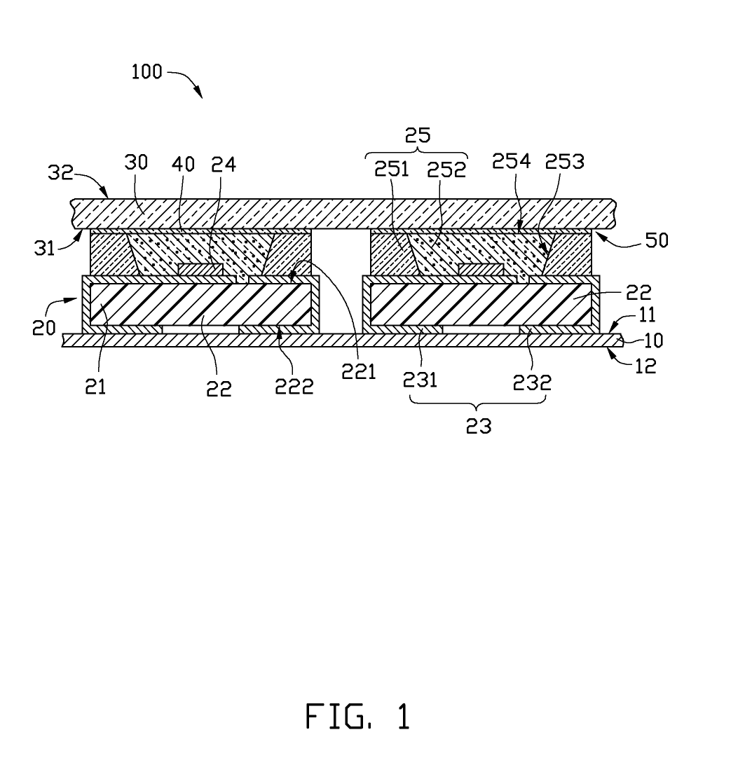

Referring to FIG. 1, a light emitting device in accordance with a first exemplary embodiment is provided as a backlight module 100. The backlight module 100 includes a substrate 10, a light source module 20, a light guiding plate 30, and a transparent colloid 40 sandwiched between the light source module 20 and the light guiding plate 30. The transparent colloid 40 can be transparent resin or transparent silicone.

Specifically, the substrate 10 is rectangular. The substrate 10 includes a top surface 11 and a bottom surface 12 opposite to the top surface 11. The top surface 11 is flat with conductive circuit arranged thereon. The substrate 10 could be a print circuit board (PCB), a metal substrate, a silicon substrate or a ceramic substrate, etc. In this embodiment, the substrate 10 is a PCB.

The light source module 20 includes multiple light emitting units 21. In this embodiment, the number of the light emitting units 21 is two. Each of the light emitting units 21 includes a base 22, two electrodes 23 arranged on the base 22, a light emitting diode (LED) die 24 and an encapsulation body 25.

Specifically, the base 22 includes a first surface 221 and a second surface 222. The base 22 could be a silicon base, a plastic base or a ceramic base, etc. Alternatively, the base 22 could also be made of one or more of gallium arsenide (GaAs), zinc oxide (ZnO), or indium phosphide (InP), etc. The first surface 221 is adjacent to the top surface 11 of the substrate 10.

The two electrodes 23 are arranged on the base 22, and the electrodes 23 include a first electrode 231 and a second electrode 232 spaced from each other. The first electrode 231 and the second electrode 232 each are made of metal. Each of the two electrodes 23 extends from the first surface 221 to the second surface 222.

The LED die 24 is arranged on the second surface 222 of the base 22 and arranged one end of the first electrode 231 adjacent to the second electrode 232. The LED die 24 electrically connects to the first electrode 231 and the second electrode 232 via wires, which are not shown in FIG. 1. Alternatively, the LED die 24 could electrically connect with the two electrodes 23 via flip chip.

The encapsulation body 25 includes a reflector 251 and an encapsulation layer 252 filled in the reflector 251. The reflector 251 defines a recess 253 in a center thereof. The reflector 251 covers a part of the first electrode 231 and a part of the second electrode 232. The LED die 24 is received in the recess 253. The encapsulation layer 252 includes a light outputting surface 254, and the light outputting surface 254 is coplanar with a top surface of the reflector 251. The encapsulation layer 252 is made of transparent materials such as silicone. Furthermore, the encapsulation layer 252 can be mixed with fluorescent particles whereby light generated by the LED die 24 can be mixed with light generated by the fluorescent particles to generate light having a desired color.

The light guiding plate 30 includes a light incident surface 31 and a light radiating surface 32 opposite to the light incident surface 31. In this embodiment, the light incident surface 31 is parallel with the light radiating surface 32; that is the backlight module 100 is a direct type backlight module. Since the light guiding plate 30 is usually fixed to an electric component (not shown), there usually is a gap 50 between the light incident surface 31 of the light guide plate 30 and the light outputting surface 254 of the encapsulation layer 252; the gap 50 is formed due to assembly tolerance. A thickness of the gap 50 is smaller than 1 millimeter.

The transparent colloid 40 which is made of transparent resin or transparent silicone is filled in the gap 50. That is the transparent colloid 40 is sandwiched between the light incident surface 31 of the light guiding plate 30 and the light outputting surface 254 of the light source module 20. A refractive index of the transparent colloid 40 is substantially equal to that of the encapsulation layer 252 and that of the light guiding plate 30. In this embodiment, the refractive index of the transparent colloid 40 ranges from 1.4 to 1.5.

In other words, the transparent colloid 40 is sandwiched between the light outputting surface 254 and the light incident surface 31, and the refractive indices of the encapsulation layer 252, the transparent colloid 40 and the light guide plate are close to each other or equal to each other; the transparent colloid 40 respectively tightly contacts the light outputting surface 254 and the light incident surface 31. Accordingly, when the light emitted by the LED die 24 successively passes through the interface between the light outputting surface 254 and the transparent colloid 40, and the interface between the transparent colloid 40 and the light incident surface 30, the light will not be reflected back at the interfaces, and a light output of the LED dies 24 to the light guiding plate 30 of the backlight module 100 is increased. Accordingly, a light output of the backlight module 100 is increased.

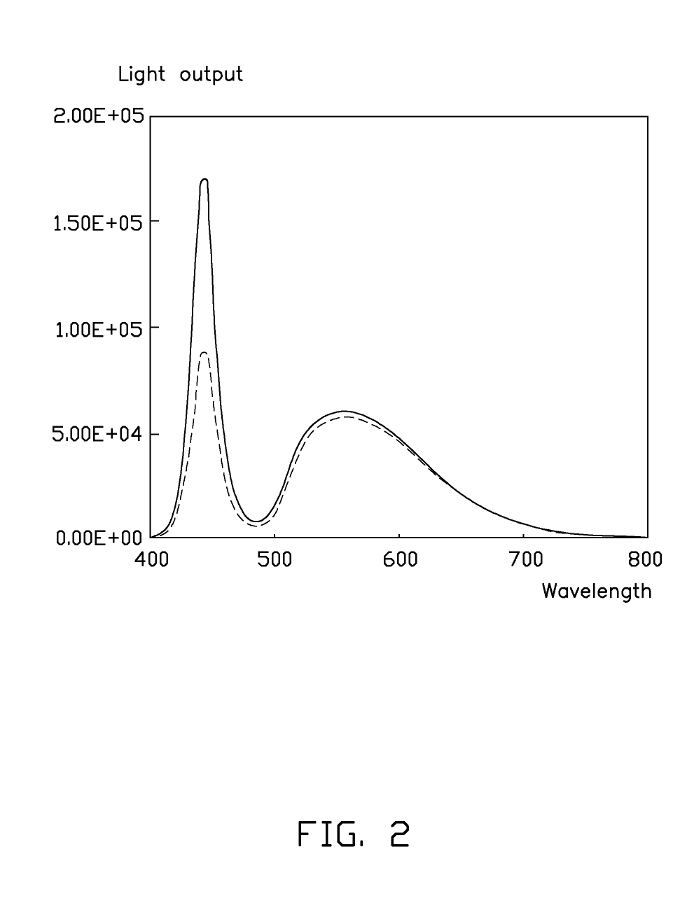

Referring to FIG. 2, the encapsulation layer 252 of the backlight module 100 is filled with a single kind of fluorescent particles. A dotted line stands an optical spectrum of a conventional backlight module, a continuous line stands an optical spectrum of the backlight module 100 of this disclosure. Since the gap 50 is filled with the transparent colloid 40, part of light with short wavelength originally being totally reflected radiates into the light guiding plate 30 via the transparent colloid 40; accordingly the light output of the backlight module 100 is increased. Compared with the conventional backlight module, the light output efficiency of the backlight module 100 is increased by 5% to 10%. Simultaneously, the light with short wavelength originally being totally reflected stimulates fluorescent particles in the encapsulation body 25 to mix and form white light, and a color temperature of the light generated from the backlight module 100 is equal to that from the conventional backlight module. In this embodiment, a weight ratio of the fluorescent particles ranges 20% to 30% of that of the encapsulation layer 252.

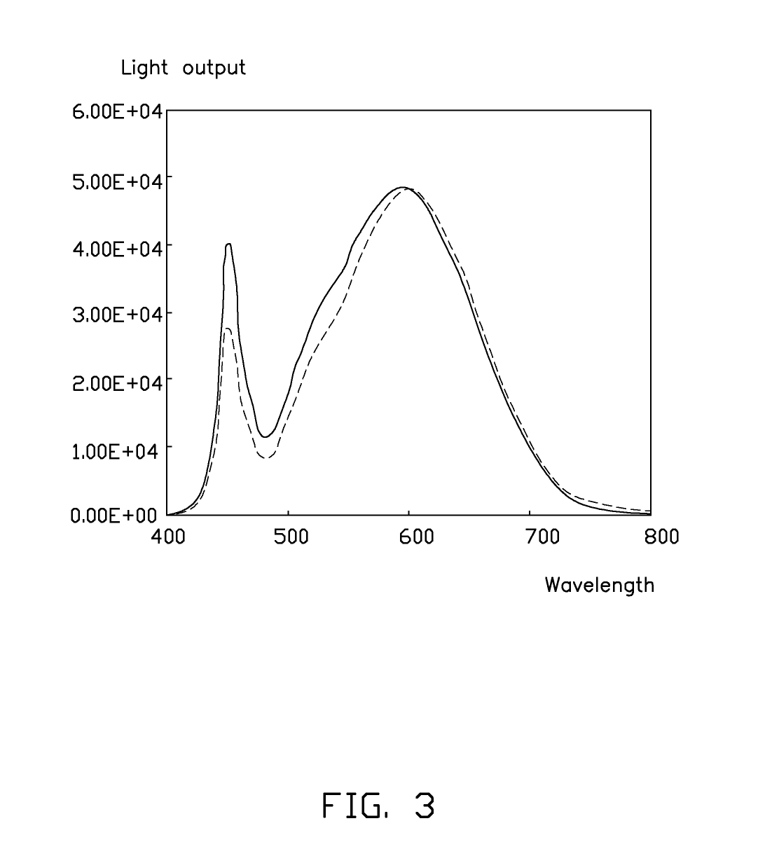

In addition, referring to FIG. 3, the encapsulation layer 252 of the backlight module 100 is filled with multiple kinds of fluorescent particles. The dotted line stands the optical spectrum of a conventional backlight module, and a continuous line stands the optical spectrum of the backlight module 100 of this disclosure. Compared with the conventional backlight module, since the light generated by the LED die 24 is absorbed by the multiple kinds of fluorescent particles to excite the fluorescent particles to generate a plurality of light beams with different wave lengths which will then be absorbed by and excite neighboring fluorescent particles to generate light beams also with different wave lengths, the light intensity of the light emitted from the light module 100 with long wavelength is decreased. That is the color temperature of the light radiating out of the light outputting surface 254 is decreased. Accordingly, when the encapsulation layer 252 is filled with multiple kinds of fluorescent particles, the weight ratio of the multiple kinds of fluorescent particles in the encapsulation layer 252 needs to be increased by 5% to 10% than that of single kind of fluorescent particles in the encapsulation layer 252, whereby the color temperature of the light generated from the backlight module 100 is equal to that from the conventional backlight module. In other words, the weight ratio of the multiple kinds of fluorescent particles ranges 25% to 40% of that of the encapsulation layer 252. Correspondingly, a transferring efficiency of the fluorescent particles is increased by 3% to 10%, and a light output efficiency of the backlight module 20 is increased by 10% to 20%.

The disclosure provides a manufacturing method for the backlight module 100 which includes following steps.

A substrate 10 is provided. The substrate 10 includes the top surface 11 and the bottom surface 12 opposite to the top surface 11. In this embodiment, the substrate 10 is a print circuit board.

A light source module 20 is arranged on the top surface of the substrate 10. The light source module 20 includes at least one light emitting unit 21. The light emitting unit 21 includes an LED die 24 and an encapsulation layer 252 covering the LED die 24. The encapsulation layer 252 includes a light outputting surface 254.

A light guiding plate 30 is arranged on the light source module 20. The light guiding plate 30 includes a light incident surface 31 and a light radiating surface 32 opposite to the light incident surface 31. The light incident surface 31 of the light guiding plate 30 faces to the light outputting surface 254 of the encapsulation layer 252. A gap 50 is defined between the light incident surface 31 of the light guiding plate 30 and the light outputting surface 254 of the encapsulation layer 252.

A transparent colloid 40 is brought to fill in the gap 50.

Before the light source module 20 and the light guiding plate 30 are fixed together, the transparent colloid 40 is applied on the top faces of the reflectors 251 and the light outputting surfaces 254, whereby when the light source module 20 is assembled to the light guiding plate 30, the transparent colloid 40 can fill in the gap 50 between the light source module 20 and the light guiding plate 30. Accordingly, both the light outputting surface 254 and the light incident surface 31 tightly contact the transparent colloid 40. Light emitted by the LED die 24 radiates to outer environment by successively moving through the light outputting surface 254, the transparent colloid 40 and the light incident surface 31 without any total reflection between the light outputting surface 254 and the transparent colloid 40, and between the transparent colloid 40 and the light incident surface 30.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A light emitting device, comprising:
a light source module comprising at least one light emitting unit, the at least one light emitting unit comprising a light emitting diode (LED) die and an encapsulation layer covering the LED die, the encapsulation layer comprising a light outputting surface;
a secondary optical element comprising a light incident surface and a light radiating surface opposite to the light incident surface, the light incident surface facing to the light outputting surface, a gap being defined between the light outputting surface and the light incident surface; and
a transparent colloid, the transparent colloid filled in the gap and intimately contacting the light incident surface of the encapsulation layer and the light incident surface of the secondary optical element.

2. The light emitting device of claim 1, wherein a refractive index of the transparent colloid is in a range from 1.4 to 1.5.

3. The light emitting device of claim 1, wherein the transparent colloid is one of transparent resin and transparent silicone.

4. The light emitting device of claim 1, wherein the encapsulation layer is filled with a single kind of fluorescent particles, and a weight ratio of the fluorescent particles ranges from 20% to 30% of that of the encapsulation layer.

5. The light emitting device of claim 4, wherein the encapsulation layer is further filled with other kinds of fluorescent particles, and a weight ratio of the multiple kinds of fluorescent particles in the encapsulation layer being greater by 5% to 10% than that of a single kind of fluorescent particles in the encapsulation layer.

6. The light emitting device of claim 1, wherein the light emitting device is a direct type backlight module, the secondary optical element being a light guiding plate, the light incident surface of the secondary optical element being parallel to the light outputting surface of the encapsulation layer.

7. The light emitting device of claim 1, further comprising a substrate, the substrate comprising a top surface, the top surface having conductive circuit arranged thereon, the light source module being arranged on the top surface of the substrate and electrically connected with the circuit.

8. A method for manufacturing a light emitting device comprising steps:
providing a light source module, the light source module comprising at least one light emitting unit, the at least one light emitting unit comprising an LED die and an encapsulation layer covering the LED die, the encapsulation layer comprising a light outputting surface;
arranging a secondary optical element on the light source module, the secondary optical element comprising a light incident surface, the light incident surface of secondary optical element facing to the light outputting surface and forming a gap with the light outputting surface; and
filling a transparent colloid in the gap.

9. The method for manufacturing the light emitting device of claim 8, wherein a refractive index of the transparent colloid is between 1.4 and 1.5.

10. The method for manufacturing the light emitting device of claim 8, wherein the transparent colloid is one of transparent silicone and transparent resin.

11. The method for manufacturing the light emitting device of claim 8, wherein the encapsulation layer is filled with a single kind of fluorescent particles, and a weight ratio of the fluorescent particles ranges from 20% to 30% of that of the encapsulation layer.

12. The method for manufacturing the light emitting device of claim 11, wherein the encapsulation layer is further filled with other kinds of fluorescent particles, and a weight ratio of the multiple kinds of fluorescent particles in the encapsulation layer being 25% to 40% of that of the encapsulation layer.

13. The method for manufacturing the light emitting device of claim 8, wherein the light emitting device is a direct type backlight module, the secondary optical element being a light guiding plate, the light incident surface of the secondary optical element being parallel to the light outputting surface of the encapsulation layer.

14. The method for manufacturing the light emitting device of claim 8, further comprising a step of arranging a substrate, the substrate comprising a top surface, the top surface being flat with conductive circuit arranged thereon, the light source module being arranged on the top surface of the substrate and electrically connected to the circuit.
